(19) United States
(12) Patent Application Publication
(10) Pub. No.: US 2007/0042575 A1
(43) Pub. Date: Feb. 22, 2007

(54) Crystallization apparatus and method of amophous silicon

(76) Inventors: Su-Gyeong Lee, SEOUL (KR); Dong-Byum Kim, Seoul (KR); Myung-Koo Kang, Seoul (KR); Ui-Jin Chung, Gyeonggi-do (KR); Hyun-Jae Kim, Gyeonggi-do (KR)

Correspondence Address: F. CHAU & ASSOCIATES, LLC, 130 WOODBURY ROAD, WOODBURY, NY, 11797, US

(21) Appl. No.: 10/549,334

(22) PCT Filed: Mar. 12, 2004
(86) PCT No.: PCT/KR04/00520

§ 371 Date: Sep. 11, 2006

(30) Foreign Application Priority Data
Mar. 13, 2003 (KR) 10-2003-0015741

(51) Int. Cl. H01L 21/20; H01L 21/36

(52) U.S. Cl. 438/488

(57) ABSTRACT

A plurality laser beams generated by a plurality of beam generators are synthesized by a beam synthesizer. The synthesized beam is splitted into a plurality of beamlets and provided for a plurality of optical units controlling the beamlets. Each beamlet controlled by each optical unit is illuminated onto an amorphous silicon layer deposited on a substrate that is mounted on a plurality of stages to be polycrystallized.

### TECHNICAL FIELD

The present invention relates to a system and a method of polycrystallization, and in particular, to a system and a method of forming a polysilicon layer of a thin film transistor array panel.

### BACKGROUND ART

Generally, silicon is classified into amorphous silicon and crystalline silicon based on its crystalline state. Since the amorphous silicon can be deposited at a low temperature to form a thin film, it is usually used for thin film transistors (TFTs) formed on a glass substrate, which has a low melting point, of a liquid crystal panel.

However, the amorphous silicon thin film has disadvantages such as low field effect mobility and thus polycrystalline silicon having high field effect mobility of about 30 cm²/V·sec, high frequency operation characteristics, and low leakage current is required.

The electrical characteristics of the polysilicon thin film are significantly affected by the size of grains. For example, the larger grains give higher field effect mobility.

A sequential lateral solidification (SLS) that grows grains in lateral directions using a laser beam is suggested to obtain large grains.

This technique uses the fact that the grain growth in a liquid phase region adjacent to a solid phase region starts at the interface between the liquid phase region and the solid phase region and proceeds along a direction perpendicular to the interface. In the SLS technique, a laser beam passes through a mask having a plurality of slit type transmissive areas arranged offset from each other and melts amorphous silicon to form liquid phase regions having a shape of the slits. Then, the liquid phase amorphous silicon becomes cooled to be crystallized. As described above, the grain growth starts from the interfaces between the liquid phase regions and solid phase regions, which are not exposed to the laser beam, and proceeds in a direction perpendicular to the interfaces, and the grains stop growing when they meet at the center of the liquid phase region. The SLS can crystallize the whole thin film by moving the mask in the direction normal to the growing direction of the grains.

In the meantime, the laser beam has a pulse shape with a limited duration. Accordingly, it is difficult to perform an SLS process with an exposure mask having large slits. Although the duration of the laser beam pulse may be extended by using a pulse duration extension (PDE) device, the addition of a device increases the manufacturing cost.

### DISCLOSURE OF INVENTION

### Technical Problem

A motivation of the present invention is to provide a system and a method of silicon crystallization, which improve the productivity and decrease the manufacturing cost.

### Technical Solution

A silicon crystallization system is provided, which includes: a plurality of beam generators generating laser beams; an optical unit controlling a synthesized beam formed by synthesizing the laser beams from the beam generators to generate an output beam; and a stage mounting a substrate provided with a silicon layer to be polycrystallized by the output beam from the optical unit.

Another silicon crystallization system is provided, which includes: a plurality of beam generators generating laser beams; a beam splitter splitting a synthesized beam formed by synthesizing the laser beams from the beam generators into a plurality of beamlets; a plurality of optical units controlling the beamlets from the beam splitter; and a plurality of stages for mounting substrates provided with silicon layers to be polycrystallized by the beamlets from the optical units.

A duration of the synthesized beam is preferably longer than each of the laser beams generated by the beam generators.

The system may further include a beam synthesizer generating the synthesized beam.

The system may further include at least one, preferably three chambers, each chamber provided with one optical unit and one stage therein.

Preferably, one of the chambers loads a substrate while another of the chambers performs polycrystallization or at least two of the chambers simultaneously perform polycrystallization.

The chambers may perform the polycrystallization in turn and the polycrystallization may include sequential lateral solidification (SLS). The silicon layer may include an amorphous silicon layer.

Another silicon crystallization system is provided, which includes: a beam generator generating a laser beam; a beam splitter splitting the laser beam from the beam generator into a plurality of beamlets; and a plurality of chambers, each chamber including an optical unit controlling one of the beamlet from the beam splitter and a stage for mounting a substrate provided with a silicon layer to be polycrystallized by the beamlet from the optical unit.

One of the chambers may load a substrate while another of the chambers performs polycrystallization.

At least two of the chambers may simultaneously perform polycrystallization.

The polycrystallization may include sequential lateral solidification (SLS) and the chambers may perform the polycrystallization in turn.

A silicon crystallization method is provided, which includes: splitting a first laser beam into a plurality of beamlets; loading a first substrate provided with a first amorphous silicon layer into a first chamber; crystallizing the first amorphous silicon layer with one of the beamlets in the first chamber; loading a second substrate provided with a second amorphous silicon layer into a second chamber during the crystallization of the first amorphous silicon layer; and crystallizing the second amorphous silicon layer with another of the beamlets in the second chamber.

The method may further include: loading a third substrate provided with a third amorphous silicon layer into the third chamber during the crystallization of the second amorphous silicon layer; unloading the first substrate from the first chamber during the crystallization of the second amorphous silicon layer; and crystallizing the third amorphous silicon layer with one of the beamlets in the third chamber.

The method may further include: generating a plurality of second laser beams; and synthesizing the second laser beams to form the first laser beam.

A silicon crystallization method is provided, which includes: splitting a first laser beam into first to third beamlets; loading a first substrate provided with a first amorphous silicon layer into a first chamber; crystallizing the first amorphous silicon layer with the first beamlet in the first chamber; loading a second substrate provided with a second amorphous silicon layer into a second chamber; crystallizing the second amorphous silicon layer with the second beamlet in the second chamber; loading a third substrate provided with a third amorphous silicon layer into the third chamber; and crystallizing the third amorphous silicon layer with the third beamlet in the third chamber, wherein the loading of the third substrate is performed during the crystallization of the first amorphous silicon layer or the crystallization of the third amorphous silicon layer.

The method may further include: generating a plurality of second laser beams; and synthesizing the second laser beams to form the first laser beam.

A duration of the crystallization of the first amorphous silicon layer overlaps a duration of the crystallization of the third amorphous silicon layer may be simultaneously performed.

The crystallization of the first amorphous silicon layer may be completed before completion of the crystallization of the third amorphous silicon layer.

### Advantageous Effects

The embodiments of the present invention facilitate an SLS process with large slits without an additional device. In addition, when using a plurality of polycrystallization chambers, the loading time of the substrates is reduced to improve the productivity and the number of the shots is reduced to decrease the manufacturing cost.

### DESCRIPTION OF DRAWINGS

The present invention will become more apparent by describing embodiments thereof in detail with reference to the accompanying drawings in which:

FIG. 1 is a schematic diagram of a silicon crystallization system according to an embodiment of the present invention;

FIG. 2 is a schematic diagram of an exemplary beam splitter of the silicon crystallization system shown in FIG. 1 according to an embodiment of the present invention;

FIG. 3A and FIG. 3B illustrates exemplary waveforms of the laser beams generated by the laser beam generator and the laser beam synthesizer shown in FIG. 1 respectively, and regions of the amorphous silicon layer liquefied by the respective laser beams;

FIG. 4 schematically illustrates an SLS process crystallizing amorphous silicon into polysilicon by illuminating a laser beam according to an embodiment of the present invention;

FIG. 5 illustrates exemplary grains of polysilicon formed by an SLS process according to an embodiment of the present invention;

FIG. 6 illustrates movement of an exposure mask in an exemplary SLS process;

FIG. 7 is a schematic diagram of a silicon crystallization system according to another embodiment of the present invention;

FIG. 8 is a schematic diagram of a beam splitter of the silicon crystallization system shown in FIG. 7 according to an embodiment of the present invention; and

FIG. 9 illustrates a polycrystallization method using the system shown in FIGS. 7 and 8 according to an embodiment of the present invention.

### BEST MODE

The present invention now will be described more fully hereinafter with reference to the accompanying drawings, in which preferred embodiments of the invention are shown. The present invention may, however, be embodied in many different forms and should not be construed as limited to the embodiments set forth herein.

In the drawings, the thickness of layers, films and regions are exaggerated for clarity. Like numerals refer to like elements throughout. It will be understood that when an element such as a layer, film, region or substrate is referred to as being ‘on’ another element, it can be directly on the other element or intervening elements may also be present. In contrast, when an element is referred to as being ‘directly on’ another element, there are no intervening elements present.

Then, systems and methods of silicon crystallization according to embodiments of the present invention are described with reference to accompanying drawings.

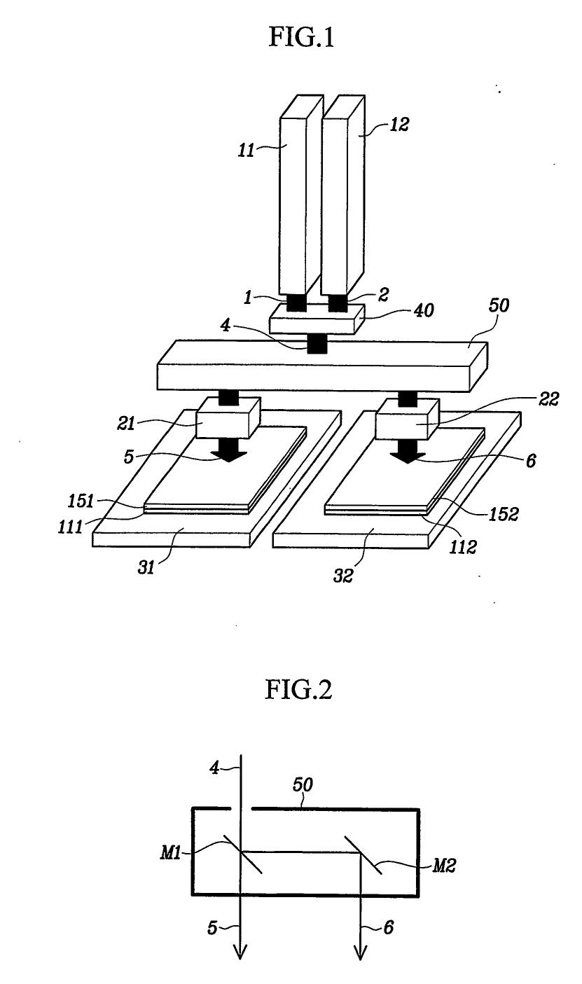

A silicon crystallization system according to an embodiment of the present invention is described in detail with reference to FIGS. 1 to 3B.

FIG. 1 is a schematic diagram of a silicon crystallization system according to an embodiment of the present invention, and FIG. 2 is a schematic diagram of a beam splitter of the silicon crystallization system shown in FIG. 1 according to an embodiment of the present invention.

Referring to FIG. 1, a silicon crystallization system according to this embodiment includes a first laser beam generator 11 generating a laser beam 1, a second laser beam generator 12 generating another laser beam 2, a laser beam synthesizer 40 synthesizing the laser beams 1 and 2 to generate a synthesized beam 4, a beam splitter 50 for splitting the laser beam 4 from beam synthesizer 40 into two beamlets 5 and 6 having equal energy, first and second optical units 21 and 22 controlling the shape and the energy of the beamlets 5 and 6 from the beam splitter 50, and first and second stages 31 and 32 mounting a liquid crystal substrates 111 and 112 and illuminated by the beamlets 5 and 6 from the optical units 21 and 22.

As shown in FIG. 2, the beam splitter 50 includes first and second mirrors M1-M2 provided therein. Each mirror M1-M2 makes an angle of about 45 degrees with a proceeding direction of the laser beam 4. The first mirror M1 partly transmits the laser beam 4 to generate a beamlet 5 having energy equal to half of the energy of the laser beam 4 incident on the beam splitter 50 and partly reflects the incident beam 4 to generate a laser beam having remaining half of the energy of the incident beam 4. The second mirror M2 fully reflects the incident beam reflected from the first mirror M1 to generate a beamlet 5.

An amorphous silicon layer 151 or 152 is deposited on each of the insulating substrates 111 and 112 to be polycrystallized by the beamlet 5 or 6 from the first or the second optical units 21 and 22.

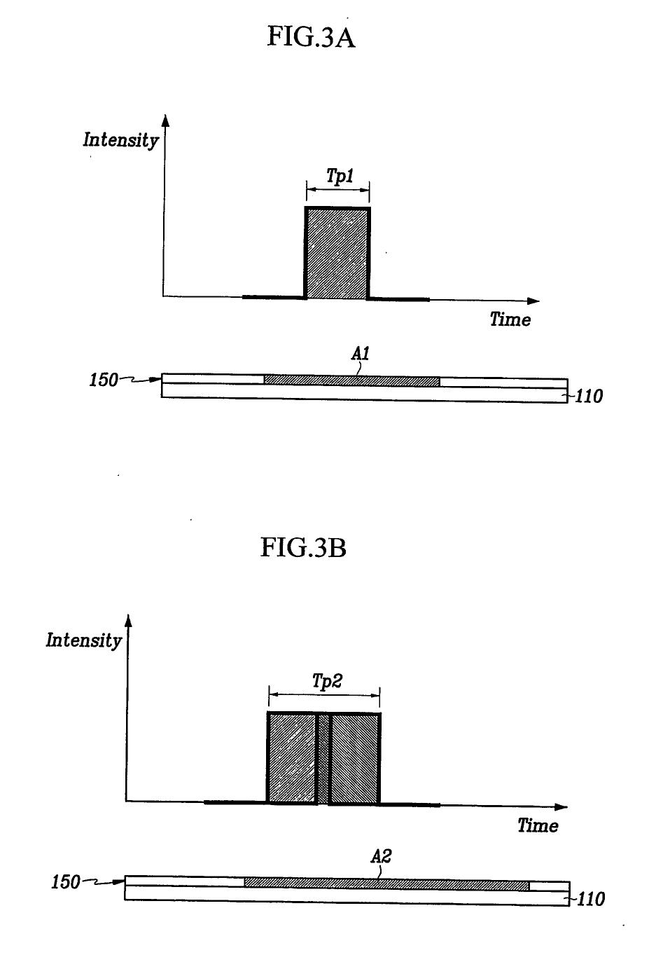

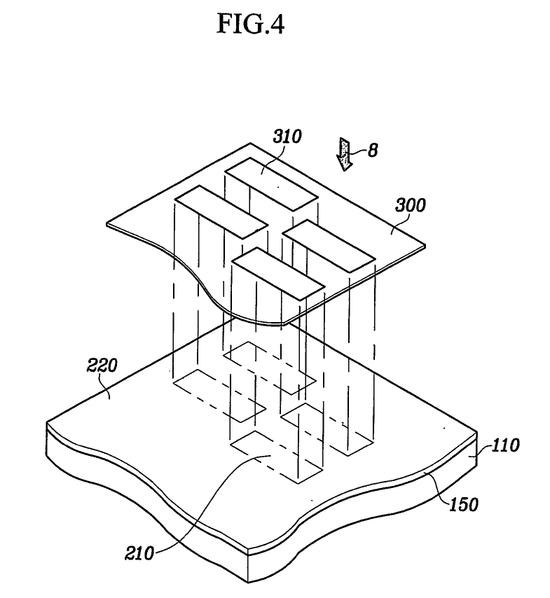

A polycrystallization method using the system shown in FIGS. 1 and 2 according to an embodiment of the present invention is described with reference to FIGS. 3A-6 as well as FIGS. 1 and 2.

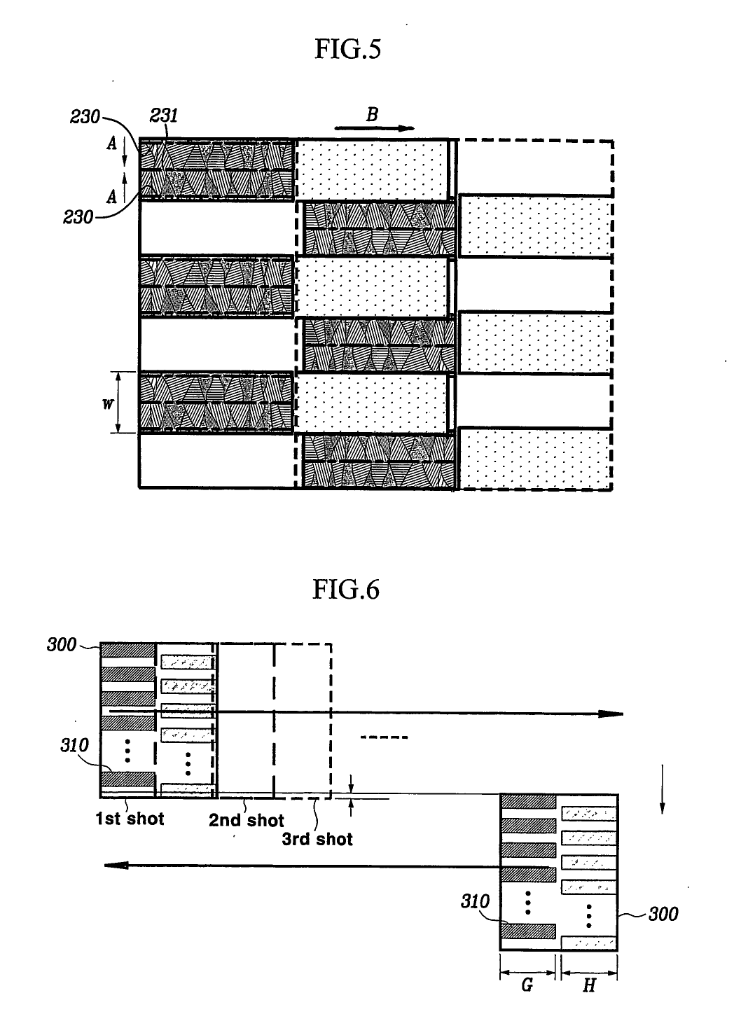

FIG. 3A and FIG. 3B illustrates exemplary waveforms of the laser beams generated by the laser beam generator and the laser beam synthesizer shown in FIG. 1 respectively, and regions of the amorphous silicon layer liquefied by the respective laser beams, FIG. 4 schematically illustrates an SLS process crystallizing amorphous silicon into polysilicon by illuminating a laser beam, FIG. 5 illustrates exemplary grains of polysilicon formed by an SLS process according to an embodiment of the present invention, and FIG. 6 illustrates movement of an exposure mask in an exemplary SLS process.

Referring to FIGS. 1 and 3A, the beam generators 11 and 12 generate respective pulse-type laser beams 1 and 2 with a time difference. The beam synthesizer 40 synthesizes the laser beams 1 and 2 to generate a synthesized pulse-type laser beam 4 shown in FIG. 3B. The synthesized pulse 4 has a duration Tp2 longer than a duration Tp1 of the beam pulse 1 or 2 generated by the beam generator 11 or 12 as shown in FIGS. 3A and 3B.

Referring to FIG. 1, the synthesized beam 4 is splitted into two beamlets 5 and 6 by the beam splitter 50, and the beamlets 5 and 6 pass through the optical units 21 and 22.

Referring to FIG. 4, each of the laser beam 5 or 6 (represented by a single reference numeral 8) onto an exposure area of an amorphous silicon layer 150 on a substrate 110 through an exposure mask 300 including a plurality of transmissive areas 310 having a slit shape. The amorphous silicon layer 150 may be deposited by low pressure chemical vapor deposition (LPCVD), plasma enhanced chemical vapor deposition (PBCVD), or sputtering. The amorphous silicon layer may be substituted with a microcrystalline silicon layer, a polycrystalline silicon layer, or a single crystalline silicon layer. An insulating layer (not shown) may be formed on the amorphous silicon layer 150. The beamlet 5 may be incident on the substrate 110 at an oblique angle, and a pair of beamlets may be incident on the substrate 110 from the top and the bottom of the substrate 110.

As shown in FIG. 6, the slits 310 of the mask 300 are elongated in a transverse direction and have a width W, and they form two columns G and H arranged in the transverse direction. The slits 310 in each column are spaced apart from each other by a predetermined distance preferably equal to the width W of the slits 310, and the slits 310 in the two columns are offset by a distance preferably equal to the width W of the slits 310. The mask 300 covers the exposure area of the amorphous silicon layer 150.

Portions of the amorphous silicon layer 150 facing the transmissive areas 310 and illuminated by the beamlet 8 are completely melted to form liquid phase regions 210, while portions indicated by reference numeral 220 remains in solid phase. The width and the length of the liquid phase regions 210 are equal to those of the slits 310. Referring to FIG. 5, the grain growth starts at interfaces 230 between the liquid phase regions 210 and the solid phase regions 210 along a direction A normal to the interfaces 230. The growing grains meet at mid-planes 231 of the liquid phase regions 210 and the grain growth stops there.

Once an exposure step (also called a shot) is finished, the mask 300 is moved by a distance equal to the length of the slits 310, i.e., equal to half of the width of the mask 300 in the length direction B of the slits 310. Then, the exposure area in the previous step partly overlaps the exposure area of this exposure step. That is, a right half of the previous exposure area becomes a left half of the this exposure area to experience light exposure again, and the solid phase areas 220 in the right half of the previous exposure area are illuminated by the beamlet 8 to become liquid phase regions. Consequently, all regions of the overlapping area of the amorphous silicon layer in the two consecutive exposure steps are polycrystallized and the grains formed in the two exposure steps have a width equal to the width W of the slits 310.

Referring to FIG. 6 again, the exposure steps are repeated from left to right and the beamlet 8 is scanned from left to right. After the scanning reaches the right edge of the amorphous silicon layer 150, the mask 300 is moved downward by a distance of its length and the scanning is stepped downward. Thereafter, the movement of the mask 300 and the scanning proceed from right to left.

In this way, all areas of the amorphous silicon layer 150 are polycrystallized.

Since the pulse duration of the beam 4 generated by the beam synthesizer 40 is increased as shown in FIGS. 3A and 3B, the illumination duration of the beamlet 8 onto the amorphous silicon layer 150 in a shot can be elongated. Accordingly, the beamlet 8 can cover a large area of the slits 310 without an additional device such as a pulse duration extension (PPE) device. For example, a region A2 shown in FIG. 3B, which can be liquefied by using the beamlet 8 generated by the beam synthesizer 40, is larger than a region A1 shown in FIG. 3A, which can be liquefied by using the laser beam 1 or 2 generated by the beam generator 11 or 12.

Consequently, the productivity is improved since the SLS process with larger slits can be performed without PDE

The numbers of the beam generators, the beamlets generated by the beam splitter, and the optical units may be varied depending on the process requirements. In order to generate three or more beamlets, the beam splitter requires additional mirrors. When the beam splitter has first to n-th mirrors for generating the beamlets, each of the intermediate mirrors partly reflects an incident laser beam from a previous mirror to generate a beamlet having energy equal to 1/n of the energy of the initial laser beam and partly transmits the incident beam to generate an output beam having remaining portions of the energy of the incident beam. Then, the output beam from the i-th mirror (1<i<n) has energy equal to (1−i/n) of the energy of the initial laser beam.

In addition, the beam splitter may be omitted and thus only one optical unit may be provided.

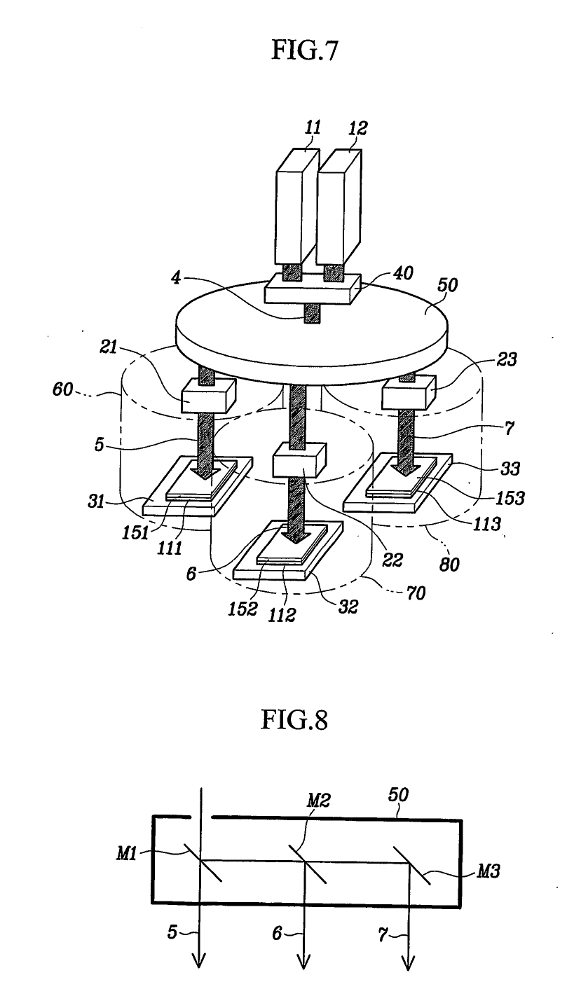

A silicon crystallization system according to another embodiment of the present invention is described in detail with reference to FIGS. 7 and 8.

FIG. 7 is a schematic diagram of a silicon crystallization system according to another embodiment of the present invention, and FIG. 8 is a schematic diagram of a beam splitter of the silicon crystallization system shown in FIG. 7 according to an embodiment of the present invention.

Referring to FIG. 7, a silicon crystallization system according to this embodiment includes a pair of laser beam generators 11 and 12 generating laser beams, a laser beam synthesizer 40 synthesizing the laser beams from the beam generator 11 and 12 to generate a synthesized beam 4, a beam splitter 50 for splitting the laser beam 4 from the beam synthesizer 40 three beamlets 5, 6 and 7 having equal energy, and first to third crystallization chambers 60, 70 and 80.

Each of the crystallization chambers 60, 70 and 80 includes an optical unit 21, 22 or 23 controlling the shape and the energy of the beamlet 5, 6 or 7 from the beam splitter 50, and a stage 31, 32 or 33 mounting a liquid crystal substrate 111, 112 or 113 provided with an amorphous silicon layer 151, 152 or 153 thereon 0 and illuminated by the beamlet 5, 6 or 7 from the optical unit 21, 22 or 23.

As shown in FIG. 8, the beam splitter 50 includes first to third mirrors M1-M3 provided therein. Each mirror M1-M3 makes an angle of about 45 degrees with a proceeding direction of the laser beam 1. The first mirror M1 partly transmits the laser beam 4 to generate a beamlet 5 having energy equal to one thirds of the energy of the laser beam 4 incident on the beam splitter 50 and partly reflects the incident beam 4 to generate a laser beam having remaining portions (1⅓) of the energy of the incident beam 4. The second mirror M2 partly reflects an incident laser beam from the first mirror M1 to generate a beamlet 6 having energy equal to one thirds of the energy of the initial laser beam 4 and partly transmits the incident beam to generate an output beam 6 having remaining two thirds of the energy of the incident beam. The last, third mirror M3 fully reflects an incident beam having energy equal one thirds of the energy of the initial laser beam 4 to generate a beamlet 7.

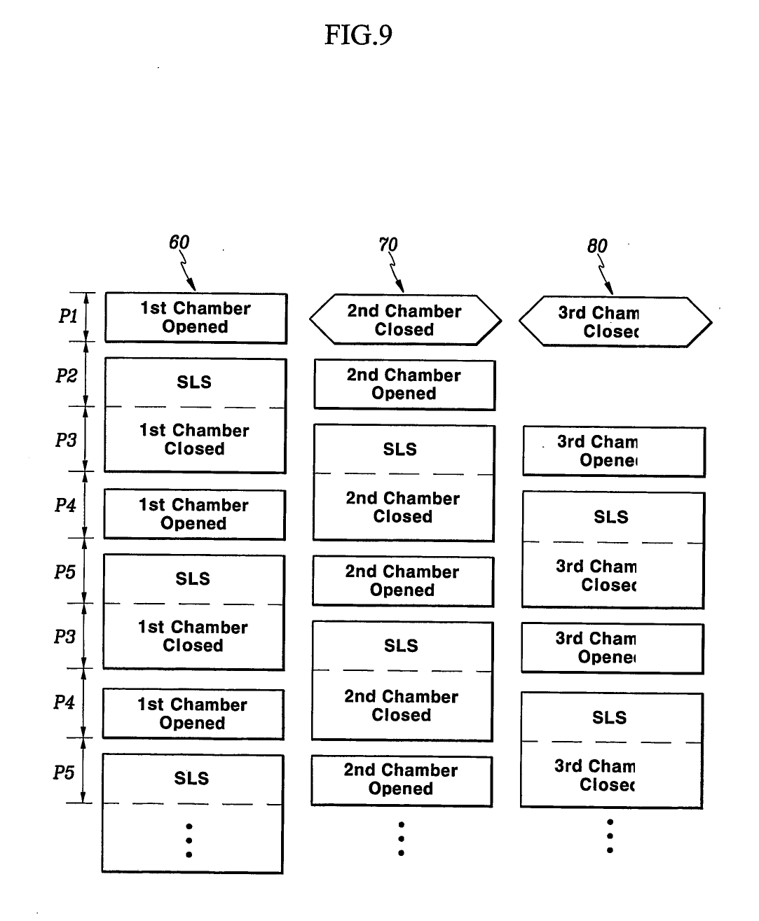

Now, a polycrystallization method using the system shown in FIGS. 7 and 8 according to an embodiment of the present invention is described with reference to FIG. 9 as well as FIGS. 7 and 8.

FIG. 9 illustrates a polycrystallization method using the system shown in FIGS. 7 and 8 according to an embodiment of the present invention.

First, an inlet (not shown) of the first chamber 60 is opened and a first substrate 111 with an amorphous silicon layer 151 is entered and loaded on the stage 31 of the first chamber 60. At this time, inlets (not shown) of the second and the third chambers 70 and 80 are closed (P1).

Next, the first chamber 60 receives a beamlet 5 from the beam splitter 50 and performs initial steps of an SLS process for the first substrate 111, and, simultaneously, the inlet of the second chamber 70 is opened and a second substrate 112 with an amorphous silicon layer 152 is entered and loaded on the stage 32 of the second chamber 70. At this time, the inlet of the third chamber 80 is still closed (P2).

Subsequently, the first chamber 60 performs later steps of the SLS process for the first substrate 111 using the beamlet 5, the second chamber 70 performs initial steps of an SLS process for the second substrate 152 using a beamlet 6 provided from the beam splitter 50, and the inlet of the third chamber 80 is opened and a third substrate 113 with an amorphous silicon layer 153 is entered and loaded on the stage 33 of the third chamber 80. After the SLS process for the first substrate 151 is completed, the first substrate 151 is unloaded from the first chamber 60 and the inlet of the first chamber 60 is closed (P3).

Consecutively, the first chamber 60 opens its inlet and loads another first substrate 111 with an amorphous silicon layer 151 on its stage 31, while the second chamber 70 performs later steps of the SLS process for the second substrate 112 using the beamlet 6, and the third chamber 80 performs initial steps of an SLS process for the third substrate 153 using a beamlet 7 supplied from the beam splitter 50. After the SLS process for the second substrate 152 is completed, the second substrate 152 is unloaded from the second chamber 70 and the inlet of the second chamber 70 is closed (P4).

Successively, while the first chamber 60 performs initial steps of an SLS process for the loaded first substrate 111 using a beamlet 5 supplied from the beam splitter 50, and the third chamber 80 performs later steps of the SLS process for the third substrate 153 using the beamlet 7, the second chamber 70 opens its inlet and loads another second substrate 112 with an amorphous silicon layer 152 on its stage 32. After the SLS process for the third substrate 153 is completed, the third substrate 153 is unloaded from the third chamber 80 and the inlet of the third chamber 80 is closed (P5).

The steps P3, P4 and P5 are repeatedly performed for several substrates.

In this embodiment, the loading time of the substrates is reduced since the polycrystallization and the substrate loading are simultaneously performed by using the system shown in FIGS. 7 and 8. In addition, since the SLS processes are continuously performed in the three chambers and the beam generators 11 and 12 continuously operate, there is no additional dummy shot except for a dummy shot at an initial oscillation, the number of the shots is reduced to decrease the manufacturing cost.

The numbers of the beam generators, the beamlets generated by the beam splitter, and the polycrystallization chambers may be varied depending on the process requirements. In addition, the beam splitter may be omitted and thus only one polycrystallization chamber may be provided.

While the present invention has been described in detail with reference to the preferred embodiments, those skilled in the art will appreciate that various modifications and substitutions can be made thereto without departing from the spirit and scope of the present invention as set forth in the appended claims.

1. A silicon crystallization system comprising: a plurality of beam generators generating laser beams; an optical unit controlling a synthesized beam formed by synthesizing the laser beams from the beam generators to generate an output beam; and a stage mounting a substrate provided with a silicon layer to be polycrystallized by the output beam from the optical unit.

2. The system of claim 1, wherein a duration of the synthesized beam is longer than each of the laser beams generated by the beam generators.

3. The system of claim 2, further comprising a beam synthesizer generating the synthesized beam.

4. The system of claim 1, further comprising a chamber provided with the optical unit and the stage therein.

5. The system of claim 1, wherein the silicon layer comprises an amorphous silicon layer.

6. A silicon crystallization system comprising: a plurality of beam generators generating laser beams; a beam splitter splitting a synthesized beam formed by synthesizing the laser beams from the beam generators into a plurality of beamlets; a plurality of optical units controlling the beamlets from the beam splitter; and a plurality of stages for mounting substrates provided with silicon layers to be polycrystallized by the beamlets from the optical units.

7. The system of claim 6, wherein a duration of the synthesized beam is longer than each of the laser beams generated by the beam generators.

8. The system of claim 6, further comprising a beam synthesizer generating the synthesized beam.

9. The system of claim 6, further comprising a plurality of chambers, each chamber provided with one of the optical units and one of the stages therein.

10. The system of claim 9, wherein one of the chambers loads a substrate while another of the chambers performs polycrystallization.

11. The system of claim 9, wherein at least two of the chambers simultaneously performs polycrystallization.

12. The system of claim 10, wherein the polycrystallization comprises sequential lateral solidification (SLS).

13. The system of claim 10, wherein the number of the chambers is three.

14. The system of claim 10, wherein the chambers perform the polycrystallization in turn.

15. The system of claim 6, wherein the silicon layer comprises an amorphous silicon layer.

16. A silicon crystallization system comprising: a beam generator generating a laser beam; a beam splitter splitting the laser beam from the beam generator into a plurality of beamlets; and a plurality of chambers, each chamber including an optical unit controlling one of the beamlet from the beam splitter and a stage for mounting a substrate provided with a silicon layer to be polycrystallized by the beamlet from the optical unit.

17. The system of claim 16, wherein one of the chambers loads a substrate while another of the chambers performs polycrystallization.

18. The system of claim 16, wherein at least two of the chambers simultaneously perform polycrystallization.

19. The system of claim 17, wherein the polycrystallization comprises sequential lateral solidification (SLS).

20. The system of claim 17, wherein the chambers perform the polycrystallization in turn.

21. A silicon crystallization method comprising: splitting a first laser beam into a plurality of beamlets; loading a first substrate provided with a first amorphous silicon layer into a first chamber; crystallizing the first amorphous silicon layer with one of the beamlets in the first chamber; loading a second substrate provided with a second amorphous silicon layer into a second chamber during the crystallization of the first amorphous silicon layer; and crystallizing the second amorphous silicon layer with another of the beamlets in the second chamber.

22. The method of claim 21, further comprising: loading a third substrate provided with a third amorphous silicon layer into the third chamber during the crystallization of the second amorphous silicon layer; unloading the first substrate from the first chamber during the crystallization of the second amorphous silicon layer; and crystallizing the third amorphous silicon layer with one of the beamlets in the third chamber.

23. The method of claim 22, further comprising: generating a plurality of second laser beams; and synthesizing the second laser beams to form the first laser beam.

24. A silicon crystallization method comprising: splitting a first laser beam into first to third beamlets; loading a first substrate provided with a first amorphous silicon layer into a first chamber; crystallizing the first amorphous silicon layer with the first beamlet in the first chamber; loading a second substrate provided with a second amorphous silicon layer into a second chamber; crystallizing the second amorphous silicon layer with the second beamlet in the second chamber; loading a third substrate provided with a third amorphous silicon layer into the third chamber; and crystallizing the third amorphous silicon layer with the third beamlet in the third chamber, wherein the loading of the third substrate is performed during the crystallization of the first amorphous silicon layer or the crystallization of the third amorphous silicon layer.

25. The method of claim 24, further comprising: generating a plurality of second laser beams; and synthesizing the second laser beams to form the first laser beam.

26. The method of claim 24, wherein a duration of the crystallization of the first amorphous silicon layer overlaps a duration of the crystallization of the third amorphous silicon layer are simultaneously performed.

27. The method of claim 26, wherein the crystallization of the first amorphous silicon layer is completed before completion of the crystallization of the third amorphous silicon layer.
